(19) United States
(12) Patent Application Publication
(10) Pub. No.: US 2024/0218245 A1
(43) Pub. Date: Jul. 4, 2024

(54) Dual-Color CsPbBr3 Nanocrystals Prepared by Water

(71) Applicant: UNIVERSITY OF KENTUCKY RESEARCH FOUNDATION, Lexington, KY (US)

(72) Inventors: Xiaobing Tang, Lexington, KY (US); Fuqian Yang, Lexington, KY (US)

(21) Appl. No.: 18/557,411

(22) PCT Filed: Apr. 27, 2022
(86) PCT No.: PCT/US22/26477

§ 371 Date: Oct. 26, 2023

Related U.S. Application Data
(60) Provisional application No. 63/180,321, filed on Apr. 27, 2021.

(51) Int. Cl. C09K 11/66; C01G 21/00; C07F 19/00; C09K 11/06; C30B 7/14; C30B 29/12

(52) U.S. Cl. CPC C09K 11/665; C01G 21/006; C07F 19/005; C09K 11/06; C30B 7/14; C30B 29/12; C01P 2002/34; C01P 2002/52; C01P 2002/72; C01P 2002/77; C01P 2002/85; C01P 2004/04; C09K 2211/181

(57) ABSTRACT

This disclosure relates to an environmental-friendly and cost-efficient approach to synthesize CsPbBr₃ powders in a large scale at room temperature with water. Using ultrasonication and centrifugation, CsPbBr₃ nanocrystals can be obtained with green (˜522 nm) and blue (˜493 nm) emissions from the powders. The photoluminescence quantum yield of the blue-emitting nanocrystals is 80%, which is much larger than 61.4% of the CsPbBr₃ nanocrystals made by an anti-solvent method. The green-emitting nanocrystals exhibit better stability than those made by the anti-solvent method over a period of 9 days. The method opens a new avenue to potentially produce inorganic and/or inorganic-organic hybrid halide perovskite nanocrystals without harmful organic solvents used in precursor solutions.

### RELATED APPLICATIONS

This application claims priority to U.S. Provisional Patent Application 63/180,321, filed Apr. 27, 2021, the content of which is hereby incorporated by reference in its entirety.

### FIELD OF THE INVENTION

This disclosure relates to methods to prepare perovskite nanocrystals in a large scale through environmentally benign approaches that result in nanocrystals with superior optical performance.

### BACKGROUND

Semiconductor nanocrystals (NCs) with outstanding characteristics of color tunability and high quantum yield have promising applications in a variety of fields, including lighting and display, solar cells, bio-imaging, and the like. To date, the most investigated NCs are cadmium-based chalcogenides NCs whose further commercialization, however, has been hindered mainly by cost issues that are associated with complex and expensive fabrication processes required to form the core-shell structure at high reaction temperatures, and structural stabilities.

Lead halide perovskite nanocrystals (PeNCs) with high brightness, wide color gamut, high color purity, high defect tolerance and a lower cost than the conventional cadmium-based chalcogenides NCs have attracted great interest for their potential applications in next-generation high-performance lighting and vivid color display. The progress in the synthesis of PeNCs has led to their rapid advancement in optoelectronic field.

Currently, most studies for the synthesis of PeNCs have been concentrated on high temperature injection (HI), room-temperature antisolvent processes, which exhibit critical drawbacks. The vacuuming of a reaction vessel, when alternated with an inert gas inflation, makes HI an intricate, time consuming and high-cost process. Further, the gas inflation can cause a suck-back of liquid/solution, which is extremely detrimental to the system and dangerous during the synthesis. These methods also pose a significant environmental threat as the solvents required for the precursor solutions, such as octadecene (ODE), dimethyl formamide (DMF), and dimethyl sulfoxide (DMSO) are toxic and volatile-organics. A shift to using environmentally benign solvents/liquids in the synthesis of PeNCs is the best option from the viewpoint of sustainability and is therefore clearly needed in the field.

### SUMMARY OF THE INVENTION

The present disclosure concerns methods to prepare perovskite nanocrystals in a large scale through environmentally benign approaches that result in nanocrystals with superior optical performance. In some aspects, the present disclosure concerns a method for preparing a cesium-lead-halide nanocrystal by adding a cesium halide and a lead halide to a volume of water. In some aspects, the cesium halide is selected from cesium bromide, cesium iodide, and cesium chloride. In some aspects, the cesium halide and lead halide have the same molarity in the volume of water.

In some aspects, the methods may include obtaining a precipitate from the volume of water and drying the precipitate. In some further aspects, the methods may also include applying heat to the precipitate at a temperature of from about 40 to 90° C. for a period of time of from about 30 minutes to about 400 minutes.

In some aspects, the methods may include placing the precipitate and/or powder in an organic solvent. In some aspects, the precipitate is provided at from about 0.02 mg to 1 mg per 3 to 15 mL of organic solvent selected from toluene, chlorobenzene, and hexane.

In some aspects, the organic solvent may further include oleic acid (OA) and/or oleyamine (OAm).

In some aspects, the methods may further include ultrasonication of the precipitate. In some aspects, ultrasonication is provided to a water bath in which there is a container containing the organic solvent with the precipitate therein. In some aspects, ultrasonication is provided for a period of from about 30 minutes to about 400 minutes. In some aspects, ultrasonication is provided at a frequency of from about 20 kiloHertz to about 10 megaHertz.

In further aspects, the volume of water further includes a metal halide to dope the cesium-lead halide nanocrystal. In some aspects, the metal halide is selected from aluminum bromide, aluminum chloride, and aluminum iodide.

In further aspects, the cesium halide may be at least partially substituted or entirely substituted with methylammonium or formamidinium.

In some aspects, the present disclosure concerns a method of preparing a cesium-lead-halide powder through adding a cesium halide and a lead halide to a volume of water. In some aspects, the cesium halide is selected from cesium bromide, cesium iodide, and cesium chloride. In some aspects, the method may include applying heat to the volume of water at a temperature of from about 40 to 90° C. for a period of time of from about 30 minutes to about 400 minutes. In further aspects, the volume of water may further include a metal halide to dope the cesium-lead halide nanocrystal. In further aspects, the cesium halide is substituted, either partially or entirely, with methylammonium and/or formamidinium.

In some aspects, the present disclosure concerns the cesium or cesium-substituted lead halides powders and/or nanocrystal produced by the methods set forth herein.

### BRIEF DESCRIPTION OF THE DRAWINGS

FIG. 1 shows the overall scheme for the preparation of CsPbBr₃ powders: (a) shows the schematic for the preparation of a film on a glass slide from CsPbBr₃ powders; (b) shows optical images showing the change of a white layer to a brown one under white light at two instants; (c) shows optical images corresponding to the ones in (b) under UV light of 365 nm; (d) shows optical images of brown powders under white light (left) and UV light of 365 nm (right); and (e) shows PL spectrum of the brown powders excited under of UV light of 365 nm.

FIG. 2 shows XRD patterns of fresh white precipitates and brown powders from fresh white precipitates heated at 40° C. for 1 h. The XRD patterns are well coincident with PDF card #73-2478 and ICSD #98-002-5124 of Cs₄PbBr₆, PDF card #72-7929 of CsPbBr₃, and PDF card #85-0189 of PbBr₂, respectively.

FIG. 3 shows the corresponding crystal model for CsPbBr₃.

FIG. 4 shows TEM images of CsPbBr₃ NCs. (a)-(b) show CsPbBr₃ NCs from the CsPbBr₃ powders by ultrasonication; and (c) shows CsPbBr₃ NCs prepared by antisolvent method. Insets show the corresponding HRTEM images.

FIG. 5 shows optical characteristics of the CsPbBr₃ NCs prepared by ultrasonication and antisolvent: (a)-(c) show PL spectra; (d)-(f) show absorption curves; and (g)-(i) show the TCSPC measurements curves.

FIG. 6 shows PL shows spectra of the CsPbBr₃ NCs prepared by two different approaches over a period of 9 days: 6(a) CsPbBr₃ NCs prepared by ultrasonication with the sonication time of 100 min and no centrifugation, and 6(b) shows CsPbBr₃ NCs prepared by antisolvent method.

FIG. 7 shows energy dispersive X-ray (EDX) spectrum of brown (CsPbBr₃) powders.

FIG. 8 shows optical images of the aqueous solutions with equimolar CsBr and PbBr₂ in DI water at various stages: (a) shows initial state; (b) shows after shaking; and (c) shows several minutes after shaking.

FIG. 9 shows fluorescent images of CsPbBr₃ powders in toluene after ultrasonication for different durations: (a) shows initial state; (b) shows 20 min; (c) shows 60 min; and (d) shows 100 min. The excitation wavelength is in a range of 340 nm-380 nm.

FIG. 10 shows PL spectra of the CsPbBr₃ powders in toluene for different durations of ultrasonication.

FIG. 11 shows variation of λ⁻¹ with Rₐ⁻² for the CsPbBr₃ NCs.

FIG. 12 shows PL of CsPbBr₃ NCs without (left peak) and with (right peak) OA.

FIG. 13 shows PL spectrum of Al-doped CsPbBr₃ powder with PL wavelength at ˜615 nm.

FIG. 14 shows PL spectrum of CsPbBr₃ powder with PL wavelength at ˜529 nm.

FIG. 15 shows PL spectrum of MAPbBr₃ NCs solution with PL wavelength at ˜526 nm.

### DETAILED DESCRIPTION

The present disclosure concerns perovskite nanocrystals and novel methods to prepare the same. In some aspects, the nanocrystals produced by the methods herein possess a different brightness and/or color gamut than they would be expected to if produced by more conventional methods. In some aspects, this disclosure concerns the development of an environmentally sensitive and green route to synthesize inorganic cesium-lead-halide perovskite nanocrystals (PeNCs), such as cesium(Cs)-lead(Pb)-bromide(Br) (CsPbBr₃) PeNCs, or combinations thereof such as CsPbBr_{1.5}I_{1.5}, CsPbBr_{1.5}Cl_{1.5}, CsPbI_{1.5}Cl_{1.5}, cation-mixed lead-halide PeNCs (such as MA_{0.5}Cs_{0.5}PbBr₃ PeNCs) and lead-free cesium-tin-halide PeNCs (such as cesium-tin-iodide (CsSnI₃) PeNCs, cesium-tin-chloride (CsSnCl₃) PeNCs). In some aspects, the PeNCs can be additionally doped with a further metal, such as aluminum. In some aspects, the cesium can be replaced or at least partially replaced with a further cation, such as methylammoium or formamidinium.

In some aspects, the methods and processes set forth herein utilize water, such as deionized (DI) water, instead of the established standard of using organic solvents to prepare PeNCs. As set forth herein, the disclosure demonstrates the methods of producing PeNCs with CsPbBr₃.

In some aspects, the methods of the present disclosure concern the formation of powdered cesium lead halides. In some aspects, the present disclosure concerns the further step of forming PeNCs from the powders. In some aspects, the present disclosure concerns ultrasonication of the powder in an organic solvent, wherein the ultrasonicastion is applied through a water bath with the powder/organic solvent in a container placed therein. The hydrochromic properties of CsPbBr₃ NCs are realized from the “reversible” transformation between a green luminescent CsPbBr₃ (emission wavelength of ˜522 nm) and a non-luminescent structure Cs₄PbBr₆ in water. In some aspects, the present disclosure concerns blue CsPbBr₃ PeNCs (emission wavelength of ˜493 nm) that can be produced via a powerful ultrasonication and centrifugation at room temperature. The CsPbBr₃ NCs as prepared herein by ultrasonication exhibit enhanced optical stability compared to those prepared by an anti-solvent method.

Currently, the blue-emitting Cs-based lead (Pb) nanocrystals (NCs) are achieved with mixed halides (i.e., CsPbBrxCl₃₋ₓ). Such resulting NCs experience critical instability of electroluminescence (EL) for CsPbBrxCl₃₋ₓ-based light emitting diodes, because the migration of the halogen ions causes the phase segregation into Cl-rich and Br-rich phases under illumination and voltage bias (Li, G. et al. Advanced Materials 28, 3528-3534 (2016); Hoke, E. T. et al. Chemical Science 6, 613-617 (2015); Draguta, S. et al. Nature Communications 8, 1-8 (2017); Vashishtha, P. & Halpert, J. E. Chemistry of Materials 29, 5965-5973 (2017)). Also, the use of chloride increases the costs.

In some aspects, the present disclosure solves the shortcomings of current methodologies and sets forth herein a facile green-route approach to achieve blue-emitting Cs-based lead-perovskite NCs (PeNCs) by using pure bromide, i.e. CsPbBr₃ NCs. The CsPbBr₃ NCs as prepared herein have the potential as the emitter for blue-emitting LEDs and other optoelectronic areas.

In some aspects, the present disclosure concerns the production of a CsBr-halide powder. As set forth in the examples, the methods set forth herein can produce a CsPbBr₃ powder. CsPbBr₃ powder can be produced by introducing CsBr and PbBr₂ into water, including deionized (DI) water. In certain aspects, the CsBr and PbBr₂ are allowed to incubate therein at an ambient temperature or room temperature (RT). In some aspects, the incubation can involve incubating the CsBr and PbBr₂ in DI water for a period of time, such as from about 1 minute to several hours. In other aspects, the incubation can be assisted by providing agitation and/or stirring.

As further set forth herein, following incubation, a white precipitate can form. In some aspects, the white precipitate can then be exposed to heat and/or incubated with a heat source. In some aspects, the heat may turn the white precipitate to a yellow to brown color depending on the length of heat exposure and/or the temperature thereof.

In some aspects, the present disclosure concerns forming NCs through incubation in an organic solvent and the application of agitation, such as ultrasonication and/or centrifugation. In some aspects, the organic solvent is selected from toluene, chlorobenzxene, heaxane or combinations thereof. In some aspects, the organic solvent may also include oleaic acid and/or oleyamine. In further aspects, the present disclosure concerns placing the precipitates or powders into a solution of toluene, oleaic acid (OA) and/or oleyamine (OAm) and applying a vigorous mixing process, such as ultrasonication and/or centrifugal force. For example, the application of ultrasonication and/or centrifugation provides for nanocrystal of CsPbBr₃. It will be appreciated that other halides other than bromide can similarly be utilized. As also described herein, in further aspects, the powders and/or NCs can be doped with one or more additional metals, as well as Cs itself can be substituted with another cation.

In some aspects, including OA and/or OAm can increasing the rate and/or size of NC formation. In some aspects, the level of agitation provided by ultrasonication and/or centrifugal force can affect the rate and/or size of NC formation. For example, a longer ultrasonication and/or more powerful ultrasonication can result in NC sizes from about 3 to about 200 nm in cross-sectional width, including about 5, 10, 20, 30, 40, 50, 60, 70, 80, 90, 100, 110, 120, 130, 140, 150, 160, 170, 180, and 190 nm.

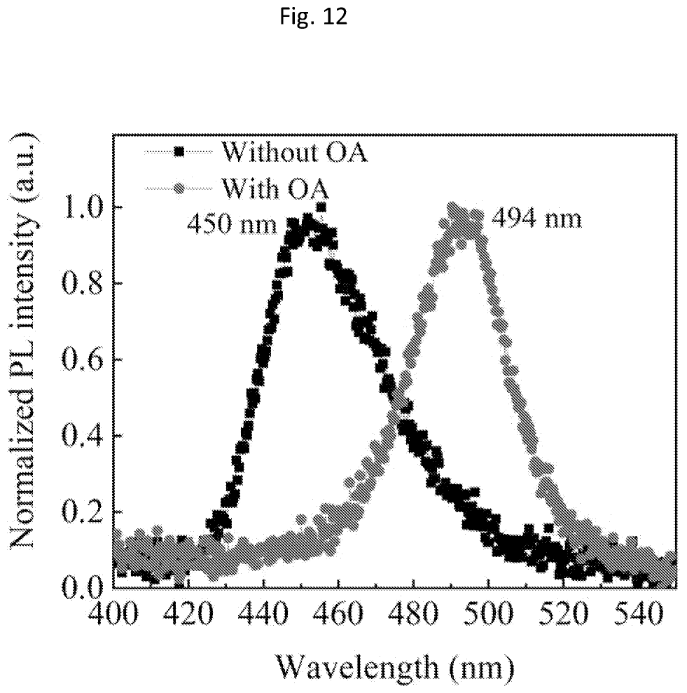

FIG. 12 shows the photoluminescence (PL) of the prepared CsPbBr₃ NCs, which exhibits a PL peak at 450 nm (left peak). The CsPbBr₃ NCs prepared by the methods set forth herein have the shortest emission wavelength (450 nm). The as-prepared CsPbBr₃ NCs under ultraviolet (UV) light (365 nm), provide a deep blue emission with respect to the emission wavelength of 450 nm. It was also identified that the PL peak experienced a red shift after adding oleic acid (OA) caused the as-prepared NCs in toluene, as shown by right peak in FIG. 12. The PL of the sample with OA is ˜494 nm.

In further aspects, the present disclosure also concerns another method to produce lead-halide nanocrystals (NCs) without the use of precursor solution by the ultrasonicating of precursor powders in OAm, which avoids the use of toxic organic solvent like dimethyl sulfoxide (DMSO), dimethyl formamide (DMF), etc. While a probe-type ultrasonicator can be utilized to sonicate a mixture with precursor powders, ligands and toluene can produce lead-halide nanocrystals (NCs), the use of a probe of an ultrasonicator frustrates the ability to seal the container with NCs, thereby allowing the solvent to evaporate quickly. Herein, is an alternative approach that removes the ultrasonic probe and implementing the ultrasonication in an ultrasonic bath at room temperature. In such instances, the sample container can be sealed.

### Green Synthesis of CsPbBr₃ Powders

In some aspects, the present disclosure concerns CsPbBr₃ nanocrystals (NCs) produced using non-toxic and environmentally sensitive reaction materials. In certain aspects, the present disclosure concerns the preparation of CsPbBr₃ NCs through the use of water. In certain aspects, the present disclosure concerns preparing CsPbBr₃ powder and then ultrasonication thereof to obtain NCs. In some aspects, the initial powder may be prepared through mixing in water, followed by ultrasonication in a solution of water or toluene or toluene and OA or toluene and OAm.

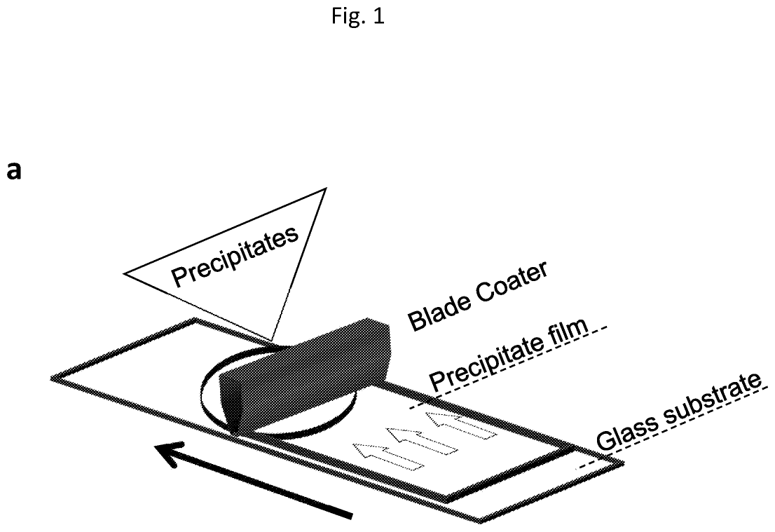

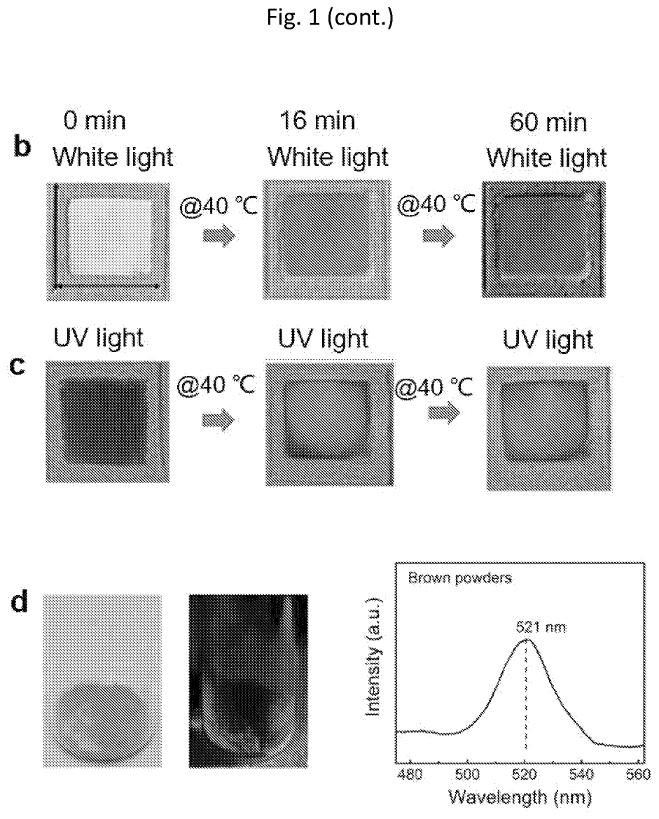

In certain aspects, the CsPbBr₃ NCs can be derived from CsPbBr₃ powders via ultrasonication. For the preparation of CsPbBr₃ powders, placing CsBr and PbBr₂ in DI water at room temperature can produce white precipitates (Cs₄PbBr₆ and PbBr₂). In some aspects, the white precipitates can then be coated on the surface of substrate, such as a glass substrate. As set forth herein, the white precipitates were coated on the surface of a glass substrate of 2.5×2.5 cm² by a blade coater to form a white thin layer, as shown schematically in FIG. 1a. The substrate with the coated white precipitate can then be placed in or near a heat source, such as a heat source of between about 30 to 60° C., including about 31, 32, 33, 34, 35, 36, 37, 38, 39, 40, 41, 42, 43, 44, 45, 46, 47, 48, 49, 50, 51, 52, 53, 54, 55, 56, 57, 58, and 59° C. and for a period of time from about 10 to about 120 minutes or more, including about 15, 20, 25, 30, 35, 40, 45, 50, 55, 60, 65, 70, 75, 80, 85, 90, 95, 100, 105, 110, 115 and 120 minutes or higher. As described herein, the glass with the white thin layer was placed on a hot plate, heated to 40° C. and maintained at 40° C. for a certain time period (FIG. 1b). In some aspects, heating the precipitate can provide a yellow to a brown powder depending on the length of time and/or temperature the precipitates are exposed to. As set forth herein, the white thin layer after 16 min heating changed to a yellow thin layer, which emitted green light under UV light (365 nm, same hereinafter). Further heating the coated thin layer for a total of 60 min led to the change of the white thin layer to a brown thin layer, which emitted green light (FIG. 1c). Such behavior is in sharp contrast to the nonluminous white one and suggests a phase transformation or the formation of new material during the heating.

The brown powders, as shown in FIG. 1d, were collected by scraping the brown film from the surface of the glass substrate. The photoluminescence (PL) spectrum of the brown powders exhibits a single PL peak centered at ˜522 nm, confirming the formation of CsPbBr₃.

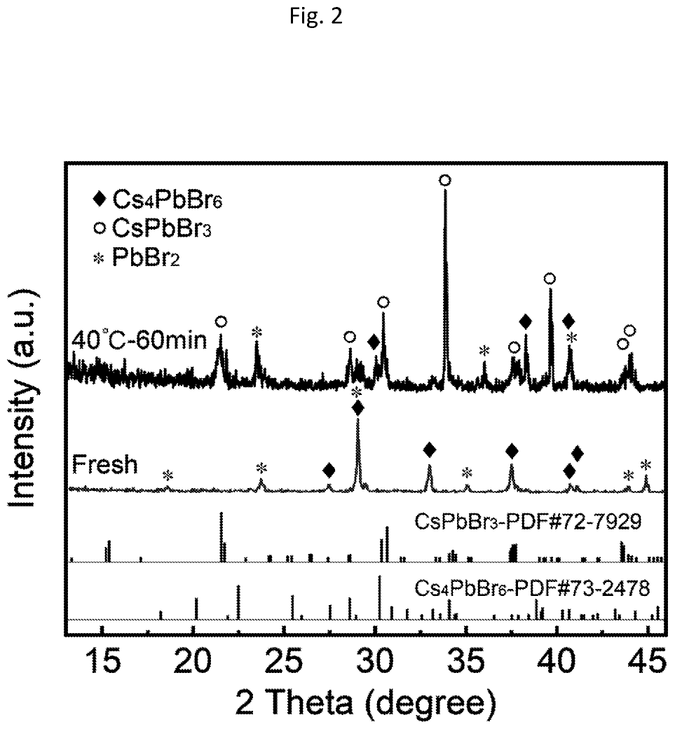

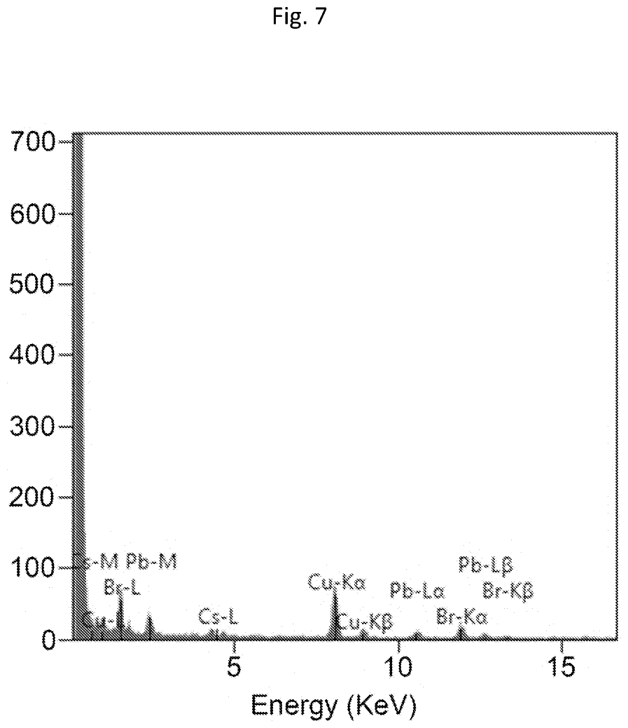

The crystallographic structure of the white precipitates and brown powders were determined on an X-ray diffractometer (XRD) (Bruker D8). The XRD patterns are depicted in FIG. 2. The lower XRD pattern, which matches the standard JCPDS card (PDF #73-2478) and ICSD #98-002-5124, indicates that the white precipitates are Cs₄PbBr₆ of hexagonal structure; the upper XRD pattern, which matches the standard JCPDS card (PDF #72-7929), confirms that the brown powders are CsPbBr₃ of orthorhombic structure with small trace of Cs₄PbBr₆ and PbBr₂ (JCPDS card (PDF #85-0189)) (Chen, X. et al. Advanced Functional Materials 28, 1706567 (2018); Quan, L. N. et al. Advanced Materials 29, 1605945 (2017); Park, S. et al. Nanoscale 11, 18739-18745 (2019); Akkerman, Q. A. et al. Nano Letters 17, 1924-1930 (2017)). The presence of Cs₄PbBr₆ and PbBr₂ can be attributed to the incomplete reaction of Cs₄PbBr₆ with PbBr₂ to form CsPbBr₃. The elemental composition of the brown powders was further analyzed on an energy dispersive X-ray (EDX) (FEI Quanta 250 Features) and presented in FIG. 7 and Table 1. The elemental ratio of Cs:Pb:Br is 16.42:17.78:65.80, which is close to the stoichiometry of CsPbBr₃ and in consistence to the XRD result.

TABLE 1
Elemental fraction of brown (CsPbBr₃) powders

| | | | Atomic | Atomic | Mass | Mass | Fitting |
|---|---|---|---|---|---|---|---|
| | Atomic | | Fraction | Error | Fraction | Error | Error |
| Element | No. | Series | (%) | (%) | (%) | (%) | (%) |
| Br | 35 | K | 65.80 | 7.19 | 47.26 | 3.87 | 1.64 |
| Cs | 55 | L | 16.42 | 2.33 | 19.62 | 2.39 | 1.74 |
| Pb | 82 | L | 17.78 | 2.60 | 33.12 | 4.20 | 2.15 |

Using the Scherrer equation and the XRD pattern, the crystallite sizes of Cs₄PbBr₆, CsPbBr₃ and PbBr₂ were obtained as 40.6, 22.7 and 29.6 nm, respectively, and the relative weight fractions of Cs₄PbBr₆ and PbBr₂ in the white precipitates as 56.9%, and 43.1%, respectively. The corresponding molar fractions of Cs₄PbBr₆ and PbBr₂ in the white precipitates are 28.5% and 71.5%, respectively, which gives the molar ratio of Cs₄PbBr₆ to PbBr₂ as ˜1:3. This result is consistent with the molar ratio of Cs₄PbBr₆ to PbBr₂ remained in the brown powders.

The reactions involving the processes of forming the CsPbBr₃ powders are illustrated below:

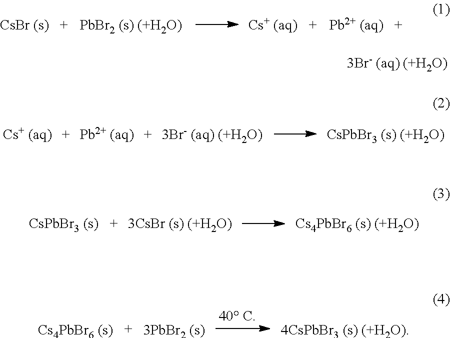

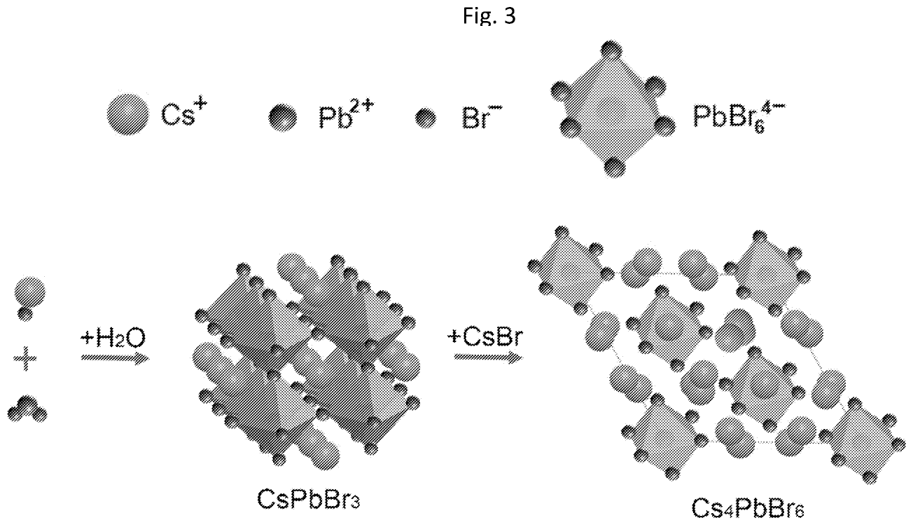

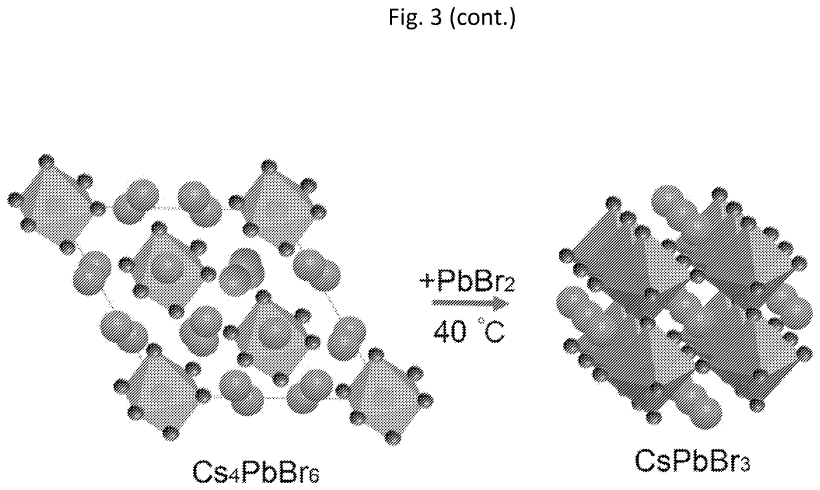

FIG. 3 shows a proposed arrangement within the crystal structure.

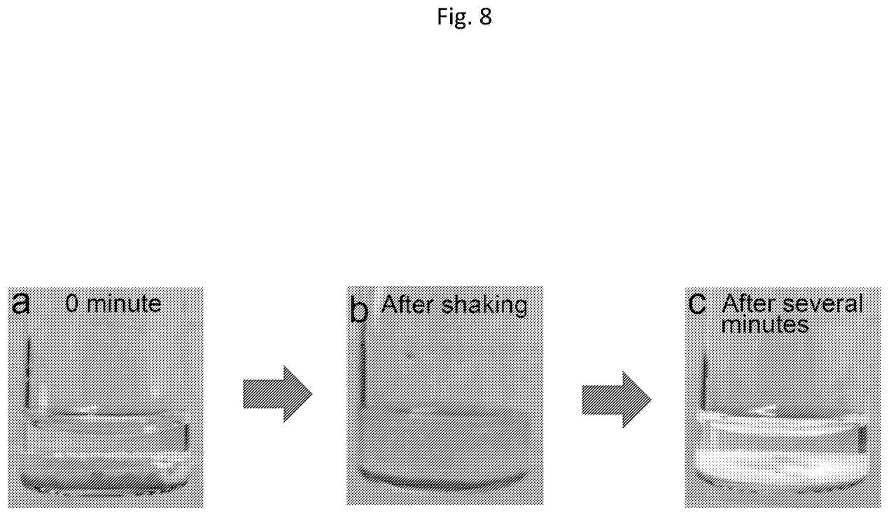

First, mixing CsBr and PbBr₂ powders in DI water leads immediately to the formation of brown CsPbBr₃ in water (FIG. 8a-8b). Note that the solubility of PbBr₂ in water is much smaller than CsBr in water. The brown CsPbBr₃ precipitates in water, leading to the dissolution of more PbBr₂ and the formation of more CsPbBr₃ in water. The brown CsPbBr₃ then reacts with CsBr in water to form white Cs₄PbBr₆ precipitates (FIG. 8c). The reaction results in the residual of PbBr₂ precipitated in water. The heating of the mixture of Cs₄PbBr₆ and PbBr₂ at 40° C. leads to the formation of CsPbBr₃ of orthorhombic structure (FIG. 1b) (Akkerman, Q. A. et al. Nano Letters 17, 1924-1930 (2017)).

According to the reaction of (4), the ratio of the stoichiometric coefficients of Cs₄PbBr₆ to PbBr₂ for the formation of CsPbBr₃ is 1:3. Such a ratio is in accord with the XRD results in FIG. 2 that the relative weight fractions of Cs₄PbBr₆ and PbBr₂ in the white powders, as obtained directly from the water solution, are 56.9%, and 43.10%, respectively, corresponding to ˜1:3 for the ratio of the molar fractions of Cs₄PbBr₆ to PbBr₂ in the white powders. This result supports the reaction of (4) indirectly.

CsPbBr₃ NCs Derived from CsPbBr₃ Powders

In further aspects, the present disclosure concerns preparation of CsPbBr₃ NCs from the CsPbBr₃ powders. In some aspects, the NCs can be prepared by applying a vigorous shaking and/or force thereto, such as application of ultrasonication and/or centrifugation. In further aspects, the precipitates as described herein are placed in a solution of toluene and therein ultrasonication and/or a centrifugal force is applied. In certain aspects, the solution may further include oleic acid (OA) and/or oleyamine (OAm). In some aspects, the OA is present with respect to the OAm in a ratio of about 2 to 1. In some aspects, for every one mole of OAm, the solution may include about 2.9, 2.8, 2.7, 2.6, 2.5, 24, 2.3, 2.2, 2.1, 2.0, 1.9, 1.8, 1.7, 1.6, 1.5, 1.4, 1.3, or 1.2 moles of OA. In further aspects, to presence of OA with respect to toluene is of from about 1:100 to about 1:400, including 1:110, 1:120, 1:130, 1:140, 1:150, 1:160, 1:170, 1:180, 1:190, 1:200, 1:210, 1:220, 1:230, 1:240, 1:250, 1:260, 1:270, 1:280, 1:290, 1:300, 1:310, 1:320, 1:330, 1:340, 1:350, 1:360, 1:370, 1:380, and 1:390.

In some aspects, the powders/precipitates in toluene, optionally with OA and/or OAm are subjected to ultrasonication for a period of from about 30 minutes to about 400 minutes or longer, including about 2, 3, 4, 5, 6, 7, 8, 9, 10, 20, 30, 40, 50, 60, 70, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, and 390 minutes. In other aspects, the ultrasonication may be of a period of about 1 to about 10 hours or more including 2, 3, 4, 5, 6, 7, 8, and 9 hours. In some aspects, the ultrasonication can be at a frequency of from about 20 kiloHertz (kHz) to about 10 megaHertz (MHz), including about 30, 40, 50, 60, 70, 80, 90, 100, 200, 300, 400, 500, 600, 700, 800, 900, 1000, 2000, 3000, 4000, 5000, 6000, 7000, 8000, and 9000 kHz. In further aspects, the powders/precipitates as described herein can be centrifuged in a solution of toluene, optionally with OA and/or OAm. Centrifugal speed may be of about 1000 to about 14,000 rpm, including about 2000, 3000, 4000, 5000, 6000, 7000, 8000, 9000, 10,000, 11,000, 12,000 and 13,000 rpm. Centrifugation may be of a period from about 1 min to about 30 minutes, including about 2, 3, 4, 5, 6, 7, 8, 9, 10, 11, 12, 13, 14, 15, 16, 17, 18, 19, 20, 21, 22, 23, 24, 25, 26, 27, 28, and 29 minutes.

As set forth herein, ultrasonication provides a process by which NCs can be obtained. In some aspects, the ultrasonication is in a solution of toluene. In other aspects, ultrasonication is in a solution of oleic acid and/or oleylamine. In further aspects, ultrasonication is in a solution of toluene and oleic acid and oleyamine. As set forth herein, ultrasonicating the CsPbBr₃ powders in toluene with oleic acid (OA) and oleylamine (OAm) as ligands, allows CsPbBr₃ NCs to be obtained. In further aspects, the process may include centrifugation.

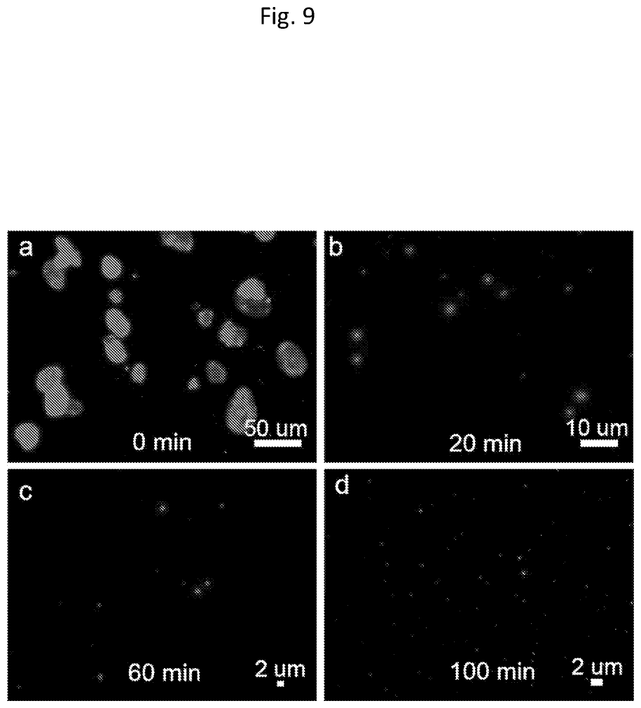

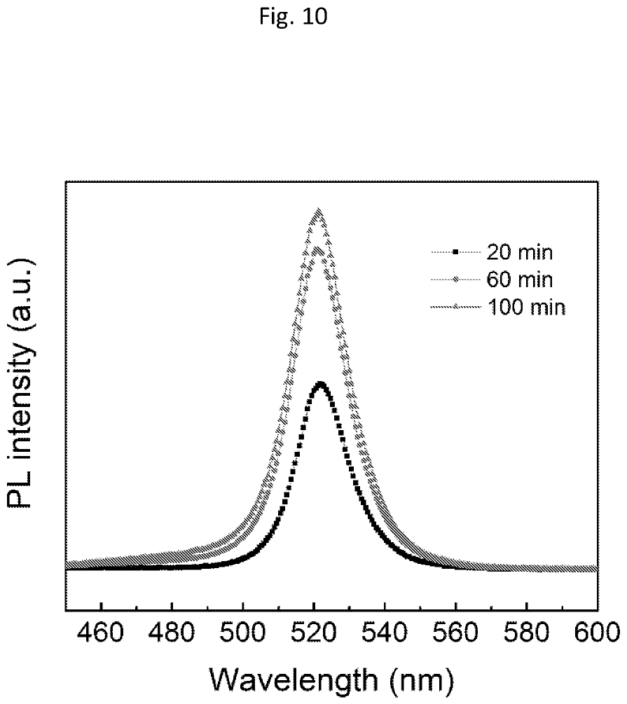

In some aspects, the concentration and size of CsPbBr₃ NCs/nanoparticles in toluene, with option OA and/or OAm, can be dependent on the duration of ultrasonication and/or the weight fraction of CsPbBr₃ powders in toluene. In some aspects, the weight fraction may be of from about 0.02 mg to 1 mg per 3 to 15 mL of toluene, including about 0.03, 0.04, 0.05, 0.06, 0.07, 0.08, 0.09, 0.1, 0.2, 0.3, 0.4, 0.5, 0.6, 0.7, 0.8, and 0.9 mg per about 4, 5, 6, 7, 8, 9, 10, 11, 12, 13, and 14 mL of toluene or toluene solution with OA and/or OAm. It is evident that the concentration of CsPbBr₃ NCs/particles increases with the increase of the ultrasonication time. More and more small CsPbBr₃ particles were produced during the ultrasonication, which was confirmed by subsequent observation on a Leica SP8 inverted confocal microscope (FIG. 9). According to FIG. 9, the ultrasonication reduced the average size of CsPbBr₃ particles from ˜35 μm to ˜200 nm after 100 min ultrasonication. The PL spectra (FIG. 10) reveals that increasing the ultrasonication time caused the increase of the PL intensity.

A simple calculation revealed that the yield of CsPbBr₃ NCs derived from the CsPbBr₃ powders can be of up to 98% (See experimental section herein). This is favorable for large-scale production of CsPbBr₃ NCs. Also, both the white power in water and brown CsPbBr₃ powders in air can be stored longer than half of a year.

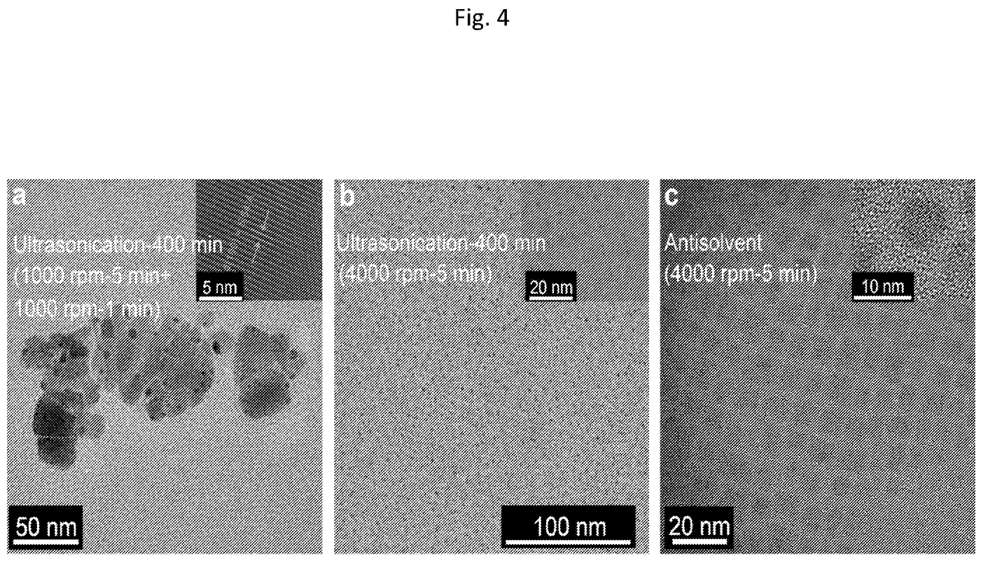

The morphologies of CsPbBr₃ NCs/particles were further characterized on a transmission electron microscope (TEM). The CsPbBr₃ NCs/particles were from a toluene suspension, which was ultrasonicated for 400 min and centrifuged at 1000 rpm for 5+1 min, and a toluene suspension, which was ultrasonicated for 400 min and centrifuged at 4000 rpm for 5 min. FIG. 4a shows a TEM image of the CsPbBr₃ particles. The average size is ˜35 nm. The HRTEM image inserted in FIG. 4a exhibits a lattice spacing of 5.64 Å, corresponding to (100) plane of CsPbBr₃ (Tang, X. et al. Advanced Science, 7, 1902767 (2020)). Increasing the centrifugation speed to 4000 rpm, allowed for CsPbBr₃ NCs of 3-5 nm in size to be obtained (FIG. 4b). These results demonstrate that one can use ultrasonication to form CsPbBr₃NCs from the CsPbBr₃ powders and the crystalline quality of the CsPbBr₃ NCs are comparable to the ones prepared from an antisolvent process (FIG. 4c).

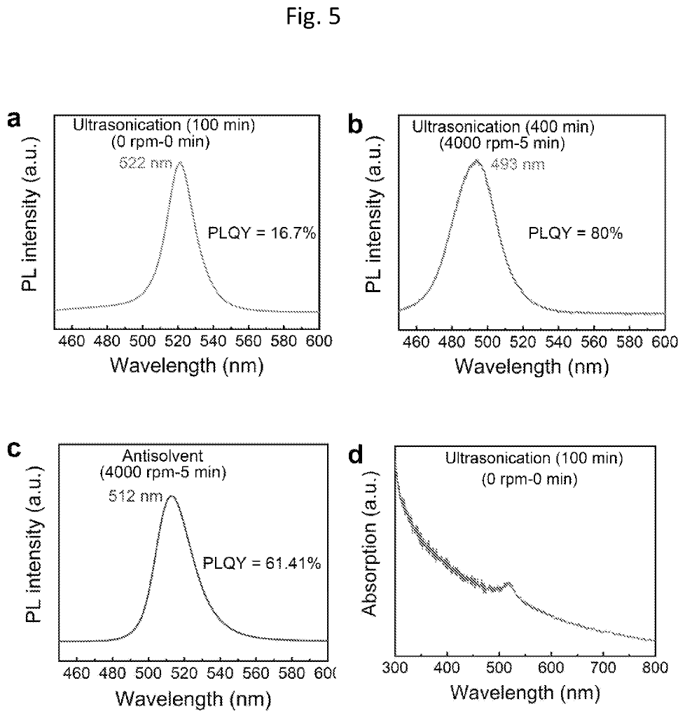

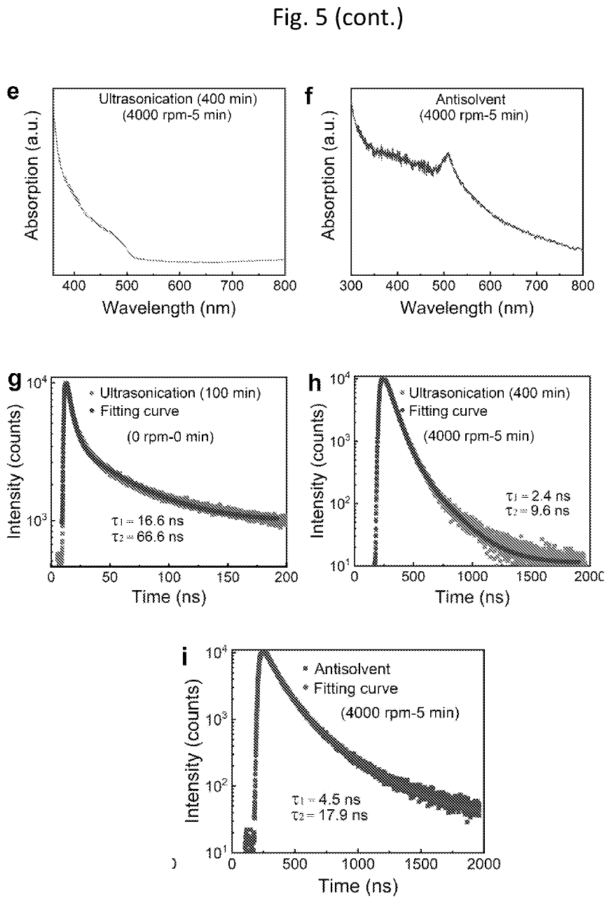

The optical characteristics of the CsPbBr₃ NCs prepared by the ultrasonication and antisolvent processes were then investigated. Here, the CsPbBr₃ NCs prepared by the antisolvent process are used as a benchmark or a control. FIGS. 5a and 5d depict the PL and absorption spectra of the CsPbBr₃ NCs from the toluene suspension, which was ultrasonicated for 100 min without centrifugation. There is a PL peak centered at ˜522 nm, and the photoluminescence quantum yield (PLQY) is 16.7%. The absorption peak is centered at ˜519 nm, and the Stokes shift is ˜3 nm. It is of note that the PL spectrum of the CsPbBr₃ NCs from the toluene suspension, which was ultrasonicated for 400 min and centrifuged at 4000 rpm for 5 min, exhibits a PL peak at ˜493 nm and the PLQY reaches up to 80% (FIGS. 5b and 5e). The PLQY of 80% is larger than 61.41% of the CsPbBr₃ NCs that were obtained from the antisolvent process (FIG. 5f), and the wavelength of the PL peak is less than −512 nm of the CsPbBr₃ NCs from the antisolvent process (FIG. 5f). There exists a blue shift, which can be attributed to the size effect of NCs (Fu, Z. et al. Applied Physics Letters 90, 263113 (2007))—the smaller the size of a NC, the shorter is the emission wavelength. FIG. 5e presents the absorption spectrum of the CsPbBr₃ NCs from the toluene suspension, which was ultrasonicated for 400 min and centrifuged at 4000 rpm for 5 min. There is a weak absorption peak at ˜490 nm, revealing a Stokes shift of ˜3 nm. The results of the Stokes shifts of the three samples indicate a comparable depth of trap states among the three samples (Janke, E. M. et al. Journal of the American Chemical Society 140, 15791-15803 (2018)). All results identify that the CsPbBr₃ NCs prepared by the ultrasonication possess superior optical performance to the ones by the antisolvent process.

According to the theory of quantum confinement, the confined ground-state excitonic energy (Eₑₓ) as a function of the average size of NCs can be expressed approximately as:

$${E}_{ex} = {E}_{g} - \frac{13.6}{{m}_{e} {ε}_{r}^{2}} \frac{{m}_{e}^{*} {m}_{h}^{*}}{{m}_{e}^{*} + {m}_{h}^{*}} + \frac{2 {π}^{2} {ℏ}^{2}}{( {m}_{e}^{*} + {m}_{h}^{*} ) {R}_{a}^{2}} \qquad ( 5 )$$

where E_{g} is the band gap of bulk semiconductor, εᵣ is relative dielectric constant, mₑ* and mₕ* are the reduced masses of electron and hole, respectively, mₑ is the mass of electron, ℏ is the Planck constant, and Rₐ is average size of NCs (Fu, Z. et al. Applied Physics Letters 90, 263113 (2007); Wu, H. et al. Journal of Crystal Growth 245, 50-55 (2002); Hanamura, E. Physical Review B 37, 1273 (1988)). The correlation between the excitonic energy and the emission wavelength is:

$${E}_{ex} = \frac{1240}{λ} \qquad ( 6 )$$

where λ is the emission wavelength in the unit of nm. Substituting Eq. (6) in Eq. (5) yields

$$\frac{1240}{λ} = {E}_{g} - \frac{13.6}{{m}_{e} {ε}_{r}^{2}} \frac{{m}_{e}^{*} {m}_{h}^{*}}{{m}_{e}^{*} + {m}_{h}^{*}} + \frac{2 {π}^{2} {ℏ}^{2}}{( {m}_{e}^{*} + {m}_{h}^{*} ) {R}_{a}^{2}} . \qquad ( 7 )$$

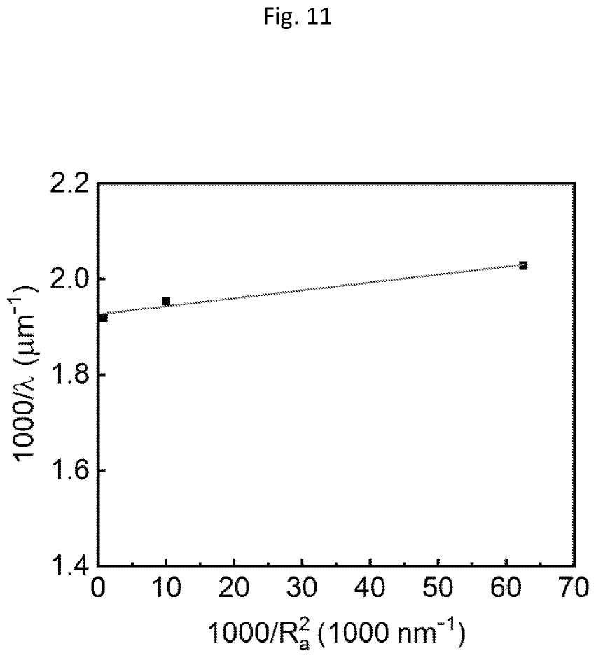

FIG. 11 shows the variation of λ⁻¹ with Rₐ⁻². It is evident that there exists a linear relation between λ⁻¹ and Rₐ⁻² in good accord with Eq. (7). The shift in the emission wavelength is due to the size effect of the CsPbBr₃ NCs.

The time-resolved PL decays of the prepared CsPbBr₃ NCs were studied at a wavelength of 390 nm at room temperature to determine the photogenerated carrier's lifetime of the CsPbBr₃ NCs (Huang, J. et al. Nano Letters 20, 3734-3739 (2020)). FIGS. 5g-5i present time-correlated single-photon-counting (TCSPC) curves of the prepared CsPbBr₃ NCs. The curves were fitted with a short decay component, Ti, and a long decay component, τ₂, corresponding to the interactive state (surface) and non-interactive state (core) of CsPbBr₃ NCs, respectively (Huang, J. et al. Nano Letters 20, 3734-3739 (2020); Yacobi, B. G. & Holt, D. B. in Cathodoluminescence Microscopy of Inorganic Solids 55-88 (Springer, 1990); Shi, D. et al. Science 347, 519-522 (2015); DuBose, J. T. & Kamat, P. V. The Journal of Physical Chemistry C 124, 12990-12998 (2020); Yoon, Y. J. et al. Nanoscale 12, 21695-21702 (2020)). For comparison, the fitting curves are also included in FIG. 5g-5i. The ratio of the long decay component to the short decay component is 4.01, 4.00 and 3.98 for the CsPbBr₃ NCs with 100 min ultrasonication and no centrifugation, with 400 min ultrasonication and 5 min centrifugation at 4000 rpm and from the antisolvent with 5 min centrifugation at 4000 rpm, respectively. There is statistically no difference between the ratios, suggesting almost the same fraction of trapping defect states. Note that the nonradiative decay is determined by trapping defect states (Glinka, Y. D. et al. Applied Physics Letters 81, 3717-3719 (2002)).

According to FIG. 5g-5i, the characteristic time for the long-lived radiative component is 66.6 ns, 9.6 ns and 17.9 ns for the CsPbBr₃ NCs with 100 min ultrasonication and no centrifugation, with 400 min ultrasonication and 5 min centrifugation at 4000 rpm and from the antisolvent with 5 min centrifugation at 4000 rpm, respectively. Such a large discrepancy in the characteristic times can be attributed to the effect of the NC size. The larger the NC size, the larger is the characteristic time for the long-lived radiative component.

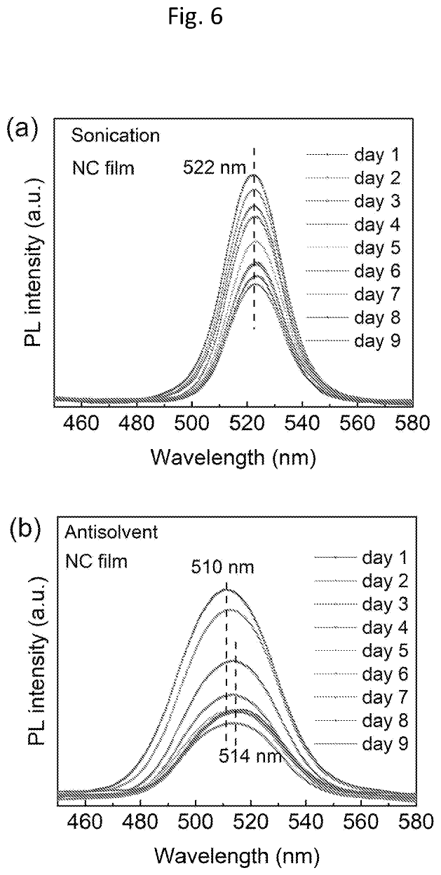

The PL stability of the prepared CsPbBr₃ NCs was evaluated over a period of 9 days at room temperature under ambient condition. The CsPbBr₃ NCs were spin-coated on the surface of indium tin oxide (ITO) substrates. The excitation wavelength of the UV light was 365 nm. FIG. 6 shows the PL spectra of the CsPbBr₃ NCs, which were made by ultrasonication from the white powders with the sonication time of 100 min and by the antisolvent method, over a period of 9 days. The PL peak of the CsPbBr₃ NCs made by ultrasonication is centered at ˜522 nm over the test period, and the PL peak of the CsPbBr₃ NCs made by the antisolvent method shifts slightly from −510 nm to ˜514 nm over the same period. The red shift of the PL peak reveals that the CsPbBr₃ NCs made by the antisolvent method experienced agglomeration and/or growth over the period likely due to the easy separation of ligands from the surface of the NCs. Such behavior suggests that the CsPbBr₃ NCs made by the ultrasonication process are relatively more stable than those made by the antisolvent method.

Accordingly, in some aspects, the present disclosure sets forth the development of a facile route for the green synthesis of CsPbBr₃ NCs without needing harmful organic solvents, such as N,N-dimethylformamide (DMF) and dimethyl sulfoxide (DMSO). In some aspects, the chemical reaction of CsBr and PbBr₂ in DI water leads to the formation of Cs₄PbBr₆ white precipitates, which can then react with PbBr₂ to form CsPbBr₃ powders. The ultrasonication and/or centrifugation of the CsPbBr₃ powders in toluene with a small amount of oleic acid (OA) and/or oleylamine (OAm) reduce the size of the CsPbBr₃ powders, resulting in CsPbBr₃ NCs of different sizes in a range of 3-200 nm for an OAm concentration larger than 50%.

The presented XRD analysis herein supports the proposed reactions for the formation of CsPbBr₃ powders via the green route with the use of only DI water. The TEM analysis of the morphologies of the CsPbBr₃ NCs illustrates that one can use the combination of ultrasonication and centrifugation to derive CsPbBr₃ NCs of ˜3 nm in size from the CsPbBr₃ powders, which can emit blue light of ˜493 nm in wavelength under the UV light of 365 nm in wavelength. It is the ultrasonic wave that interacts with the CsPbBr₃ powders and causes the fragmentation of the CsPbBr₃ powders to form CsPbBr₃ NCs. The CsPbBr₃ NCs prepared by the ultrasonication possessed slightly fewer surface defects than those by the antisolvent method and exhibited better long-term PL stability than those by the antisolvent method.

The method developed herein provides a green technique to synthesize CsPbBr₃ NCs. Such a method opens a new avenue to potentially produce inorganic halide perovskite nanocrystals without the use of harmful organic solvents in the preparation of precursor solutions.

### Aluminum-Doped NCs

In some aspects, the present disclosure concerns the preparation of an aluminum doped (Al-doped) cesium lead halide powder or NCs thereof, such as a lead bromide. In some aspects, the Al-doped CsPbBr₃ includes Al-doping of between about 0.1 to about 75% by weight of the resulting powder or NC, including 0.2, 0.3, 0.4, 0.5, 0.6, 0.7, 0.8, 0.9, 1, 2, 3, 4, 5, 6, 7, 8, 9, 10, 15, 20, 25, 30, 3, 40, 45, 50, 55, 60, 65, and 70% by weight. In some aspects, the Al-doped CsPbBr₃ is prepared by first obtaining an aluminum bromide (AlBr₃) solution, such as by dissolving aluminum in hydrogen bromide. The CsBr and PbBr₂ in equimolar concentrations are added therein, which results in a formed Al-doped CsPbBr₃ powder. The powder can then be utilized to form NCs, such as through methods described herein.

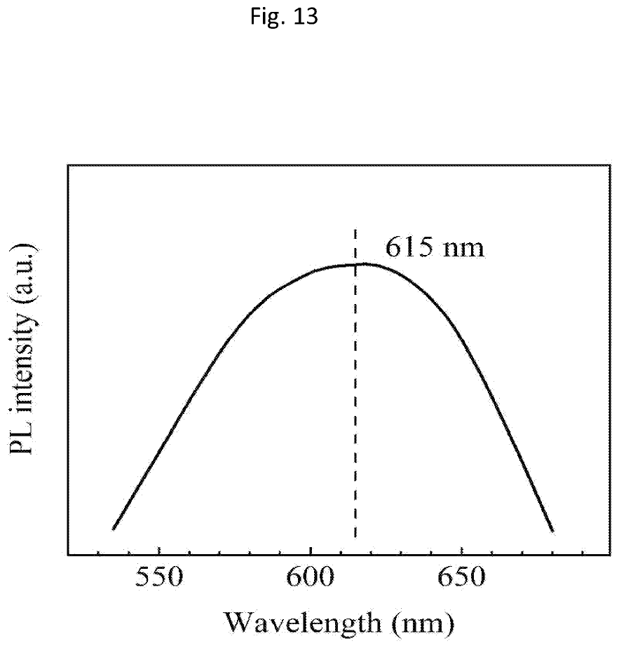

In some aspects, the Al-doped CsPbBr₃ provides a red/orange emitting powder with a PL-peak wavelength of about 615 nm (see, FIG. 13).

In some aspects, the Al-doped CsPbBr₃ powder is a green emitting powder. As set forth herein, the application of heat energy and/or the immersion in alcohol can transform the Al-doped material into a green powder. In some aspects, Al-doped CsPbBr₃ can be heated for a period of about 0.5 to about 10 hours at 50-150°, including about 1, 2, 3, 4, 5, 6, 7, 8, and 9 hrs at about 55, 60, 65, 70, 75, 80, 85, 90, 95, 100, 105, 110, 115, 120, 125, 130, 135, 140, and 145° C. In some aspects, the Al-dope CsPbBr₃ powder is immersed in an alcohol at about room temperature (RT), such as methanol, ethanol, propanol, butanol, or hexanol. For example, as set forth herein Al-doped CsPbBr₃ was heated at 100° C. for 5 hrs and then immersed in methanol which yielded a green powder (see, FIG. 13 with peak wavelength of 615 nm).

In some aspects, the amount of metal doped into the powder can affect the color and/or wavelength emitted from the resulting powder and/or NC. In some aspects, more than one metal halide may be used as a dopant. In some aspects, the dopant may be provided at a molar ratio to the lead halide of from about 1:100 to about 2:1, including about 1:90, 1:80, 1:70, 1:60, 1:50, 1:40, 1:30, 1:20, 1:10, 1:9, 1:8, 1:7, 1:6, 1:5, 1:4, 1:3, 1:2, and 1:1.

### Green-Emitting CsPbBr₃

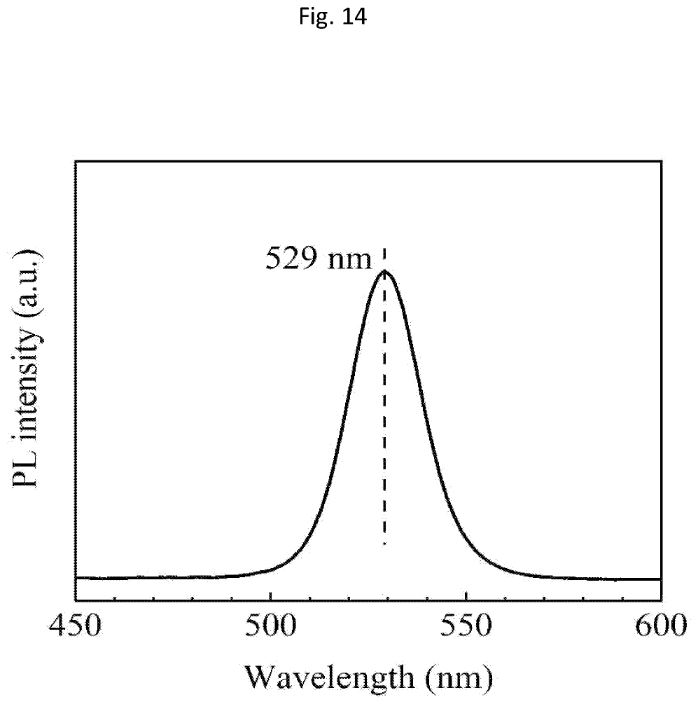

In some aspects, the present disclosure concerns green-emitting CsPbBr₃ powders and/or NCs. As described herein adding equimolar CsBr and PbBr₂ powders into water, followed by stirring and/or agitation, provides a yellow CspBBr₃ powder which then changes to orange after addition time. The resulting powder has a PL-peak wavelength of about 529 nm (see, FIG. 14).

### Cs-Substitutions

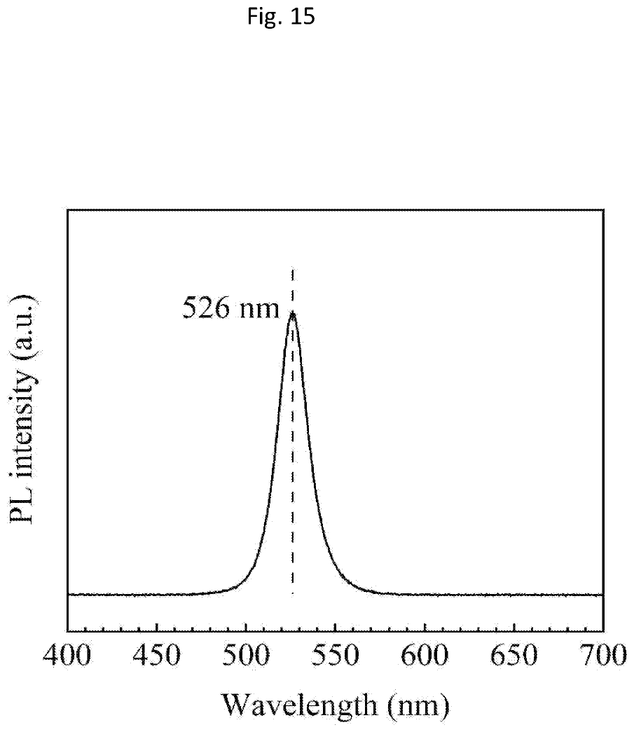

In some aspects, the present disclosure concerns replacing cesium with another cation in the powders and NCs of the present disclosure. In some aspects, cesium can be replaced with methyl ammonium (MA), such that a MAPbBr₃ powder or NC can be formed. In some aspects, MAPbBr₃ can be prepared through combining equimolar parts of MABr and PbBr₂ in water. As described herein, this can yield a white precipitate which can then be heated, such as at a temperature of about 45-80° C. for a period of about 10 mins to 3 hours, including about 50, 55, 60, 65, 70, and 75° C. for about 20, 30, 40, 50, 60, 70, 80, 90, 100, 110, 120, 130, 140, 150, 160, and 170 mins. Application of the heat can result in the white precipitate turning orange. In further aspects, the orange precipitate or powder can be prepared into NCs through mixing with toluene and/or OAm. In some aspects, NCs are formed through ultrasonication of the orange precipitate or powder, such as ultrasonication in a solution of toluene and/or OAm. In some aspects, the orange precipitate or powder is ultrasonicated for a period of about 30 to 500 mins or more, including about 50, 100, 150, 200, 250, 300, 350, 400, and 450 minutes or more. As described herein, the ultrasonication allows for the formation of NCs of MAPbBr₃, which provides a peak PL wavelength of about 526 nm (see, e.g., FIG. 15).

In some aspects, cesium may similarly be replaced with formamidinium (FΛ or CH(NH₂)₂^{|}). In some aspects, FABr can be used as described with MABr and/or CsBr to provide for powders and NCs as described herein.

### Methods of Preparation

In some aspects, the present disclosure concerns methods of preparing the powders and/or NCs as set forth herein. In some aspects, the methods can include preparing an initial powder by adding a lead halide and a cation halide together in water. In some aspects, the cation is cesium, methylammonium, or formamidinium. In some aspects, the halogen is of bromine, chlorine, or iodine. As identified herein, mixing PbBr₂ with CsBr, MABr, or FABr in water at room temperature allows for the formation of a precipitate of CsPbBr₃, MAPbBr₃, or FAPbBr₃.

In further aspects, the formed cation lead-halide may be further metal doped. For example, as set forth herein, preparing a further metal halide solution and mixing therein the lead halide and cation halide provides for a metal-doped cations lead halide powder. For example, adding CsBr and PbBr₂ powders to an AlBr₃ solution allows for an Al-doped powder to form.

In some further aspects, the powder can treated with heat for a prescribed period of time to further adjust the properties of the powder.

In some aspects, the method may further include drying the precipitate, such as through leaving exposed to atmospheric room temperature or applying a heat and/or blown air thereover.

In some aspects, the methods may include placing the precipitate into a volume of an organic solvent. As identified herein, such may include a volume of toluene, a volume of chlorobenzene, or a volume of hexane. In some aspects, the organic solvent may also include OA and/or OAm.

In some aspects, the precipitate in the organic solvent may be ultrasonicated. In some aspects, the organic solvent may be placed in a water bath and ultrasonication is applied through the water bath. For example, the precipitate may be placed in a container, such as a glass or plastic container, and the container is placed in the water bath. Therein, ultrasonication is applied. As identified herein, the ultrasonication is provided for a period of from about 30 mins to about 4 hrs or more, including about 100 mins. Ultrasonication may be performed at room temperature or at an elevated temperature of up to about 100° C.

### EXAMPLES

### Materials

CsBr (99.9%, Beantown Chemical), PbBr₂ (98+%, Strem Chemicals Inc.), N,N-dimethylformamide (DMF) (VWR), oleic acid (OA) (Ward's Science), oleylamine (OAm) (>50%, TCI America), toluene (VWR) and DI water were used in the synthesis of CsPbBr₃ NCs. All the chemicals were used as received without further purification.

### Synthesis of CSPbBr₃ NCs

The CsPbBr₃ NCs were derived from CsPbBr₃ powders via ultrasonication. For the preparation of CsPbBr₃ powders, placing CsBr and PbBr₂ in DI water at room temperature produced white precipitates (Cs₄PbBr₆ and PbBr₂). The white precipitates were coated on the surface of a glass substrate of 2.5×2.5 cm² by a blade coater to form a white thin layer, as shown schematically in FIG. 1a. The glass with the white thin layer was placed on a hot plate, heated to 40° C. and maintained at 40° C. for a certain time period (FIG. 1b). The white thin layer after 16 min heating changed to a yellow thin layer, which emitted green light under UV light (365 nm, same hereinafter). Further heating the coated thin layer for a total of 60 min led to the change of the white thin layer to a brown thin layer, which emitted green light (FIG. 1c). Such behavior is in sharp contrast to the nonluminous white one and suggests a phase transformation or the formation of new material during the heating.

The brown powders, as shown in FIG. 1d, were collected by scraping the brown film from the surface of the glass substrate. The photoluminescence (PL) spectrum of the brown powders exhibits a single PL peak centered at ˜522 nm, confirming the formation of CsPbBr₃.

Ultrasonicating the CsPbBr₃ powders in toluene with oleic acid (OA) and oleylamine (OΛm) as ligands, allowed CsPbBr₃ NCs to be obtained. The concentration and size of CsPbBr₃ NCs/nanoparticles in toluene are dependent on the duration of ultrasonication and the weight fraction of CsPbBr₃ powders in toluene.

### Synthesis of CsPbBr₃ NCs by Antisolvent Method

Following the methods reported in literature, CsPbBr₃ NCs were prepared by an antisolvent method. Briefly, a solution consisting of DMF (10 mL), OA (1 mL), OAm (0.5 mL), CsBr (0.4 mmol) and PbBr₂ (0.4 mmol) was stirred at 30° C. overnight to form a precursor solution. 1 mL of the prepared precursor solution was quickly placed in toluene (10 mL) under vigorous stirring at 30° C. to form CsPbBr₃ NCs.

### Calculation of the Yield of CsPbBr₃ NCs

15.9439 g CsPbBr₃ powders was added in a glass vial with 50 μL OA, 25 μL OAm, 5 mL toluene, followed by ultrasonication for 100 min, which led to the production of green-emitting CsPbBr₃ NCs. The CsPbBr₃ NCs were dried on a hot plate at 40° C. The final weight of the CsPbBr₃ NCs was 15.5517 g. Using these weights, the yield of the CsPbBr₃ NCs was calculated.

### Materials Characterization

XRD measurements were performed on an X-ray diffractometer (Siemens D500).

The imaging of the CsPbBr₃ NCs/powders were carried out on an inverted confocal microscope (Leica SP8). TEM and HRTEM (Thermo-scientific Talos F200X TEM operated at an accelerating voltage of 200 kV) were used to analyze the structures and morphologies of the CsPbBr₃NCs. The brown powders were further analyzed on an energy dispersive X-ray (EDX) spectroscope (Thermo-scientific Super-X System with four windowless silicon-drift-detectors (SDD) installed on a Talos F200X TEM). The PLQY and TCSPC measurements were carried out on a spectrofluorometer (FluoroMax-Plus-C) with an excitation wavelength of 390 nm.

### PL and TCSPC Measurements

PL spectra were collected on a Horiba Scientific Fluoromax Plus-C fluorometer using 2 nm entrance and exit slits and an integration time of 0.1 s for both excitation and emission scans. PL decay measurements were performed using a DeltaHub™ high throughput TCSPC controller and a NanoLED-390 pulsed excitation source (excitation wavelength 393±10 nm). TCSPC curves were collected at 425 and 465 nm emission with 5 nm bandpass at a repetition rate of 1 MHz over a measurement time of 200 ns. The instrument response function (IRF) was determined by measuring the scattering of the excitation source with a ludox sample. The fitting of decay curves was done using Horiba Scientific decay analysis software DAS6.

### UV-VIS Absorption Spectra

UV-Vis absorption measurements were carried out on a Thermo Scientific Evolution 201 Uv-Visible spectrophotometer. The samples were scanned in the wavelength range of 300-800 nm with a bandwidth of 1 nm and 0.1 s integration time.

### Absolute Photoluminescence Quantum Yield (PLQY) Measurements.

PLQY measurements were carried out using the integrated sphere connected to the Horiba Scientific Fluoromax Plus-C fluorometer. The excitation wavelengths which give the maximum emission were used in the PLQY measurements. The parameters of 0.5 nm slit width and 0.1 s integration time were used. The PLQY calculations were done using the Horiba Scientific FluorEssence™ software.

### Powder Ultrasonication

Equal molar (0.4 mmol) CsI and PbI₂ were dissolved in 1 ml OA and 0.5 ml OAm mixed solution, followed by a vigorous stirring before an ultrasonication of 100 minutes. Adding 1 ml toluene to the produced materials to form a suspension, which was ultrasonicated for 100 minutes in an ultrasonic bath at room temperature.

After this, 0.5 ml of the as-obtained products were added into 5 ml toluene and the suspension was ultrasonicated for 100 minutes in an ultrasonic bath at room temperature. This led to the formation of CsPbI₃ NCs, which were washed by toluene for further use. The other samples including CsPbI_{1.5}Br_{1.5}, CsPbBr₃, CsPbBr_{1.5}Cl_{1.5}, CsPbCl₃ have been prepared by the same procedure. All above operations were implemented at room temperature.

### Red-Emitting Al-Doped CsPbBr₃ Powder

Preparation of AlBr₃ solution. 1 mL HBr (48 wt %) was put into a vial with 0.063 g Al foil until the Al foil was dissolved completely at room temperature.

Preparation of Λl-dopped CsPbBr₃ powder. Equal molar (0.4 mmol CsBr and PbBr₂) powders were added into the above-mentioned AlBr₃ solution prepared in the first step which resulted in the formation of an orange Al-doped CsPbBr₃ powder at room temperature. The emitting light of the Al-doped CsPbBr₃ powder was turned into green from red after it was heated at 100° C. for 5 h and immersed in methanol, respectively.

### Green-Emitting CsPbBr₃ Powder by Water at Room Temperature

Equal molar (2 mmol) CsBr and PbBr₂ powders were put into a vial. 60-120 μL deionized (DI) water was then added into the mixture of CsBr and PbBr₂ gradually under stirring at room temperature. Yellow CsPbBr₃ powder was produced, and the CsPbBr₃ powder turned into orange with increasing time, as shown in FIG. 14 with a peak wavelength of 529 nm.

Green-Emitting MAPbBr₃ (MA=CH₃NH₃) Nanocrystals (NCs) by Water

Preparation of MAPbBr₃ powders. Equimolar (1 mmol) MABr and PbBr₂ were put in 2 mL deionized (DI) water, and white precipitates were formed in DI water after shaking. Moderate white precipitates were then placed on a glass plate. The glass plate with the white precipitates was heated on a hot plate at 60° C. for 30 min, leading to the formation of orange MAPbBr₃ powders. All other steps were operated at room temperature.

Preparation of MAPbBr₃ NCs. 10 mL toluene with 100 μL OΛ and 50 μL OΛm were added into 0.04 g of MAPbBr₃ powders obtained in the first step to form a mixture. Then the mixture was ultrasonicated in a water bath for 400 min, and a MAPbBr₃ NC solution was obtained. The final MAPbBr₃ NC solution was produced by a filtration of the supernatant of ultrasonicated MAPbBr₃NC solution with a 0.2 μm syringe filter. All these steps were operated at room temperature. FIG. 15 shows the resulting PL spectrum and shows the NCs to have a PL wavelength peak at about 526 nm.

A first aspect of the present disclosure, either alone or in combination with any other aspect, concerns a method for preparing a cesium-lead-halide nanocrystal, comprising adding a cesium halide and a lead halide to a volume of water.

A second aspect of the present disclosure, either alone or in combination with any other aspect, concerns the method of the first aspect, wherein the cesium halide is selected from the group consisting of cesium bromide, cesium iodide, and cesium chloride.

A third aspect of the present disclosure, either alone or in combination with any other aspect, concerns the method of the first or second aspect, wherein the cesium halide and lead halide have the same molarity in the volume of water.

A fourth aspect of the present disclosure, either alone or in combination with any other aspect, concerns the method of the first aspect, further comprising obtaining a precipitate from the volume of water and drying the precipitate.

A fifth aspect of the present disclosure, either alone or in combination with any other aspect, concerns the method of the fourth aspect, further comprising applying heat to the precipitate at a temperature of from about 40 to 90° C. for a period of time of from about 30 minutes to about 400 minutes.

A sixth aspect of the present disclosure, either alone or in combination with any other aspect, concerns the method of the fourth or fifth aspect, further comprising placing the precipitate in an organic solvent.

A seventh aspect of the present disclosure, either alone or in combination with any other aspect, concerns the method of the sixth aspect, wherein the precipitate is provided at from about 0.02 mg to 1 mg per 3 to 15 mL of organic solvent.

An eighth aspect of the present disclosure, either alone or in combination with any other aspect, concerns the method of the sixth aspect, wherein the organic solvent is selected from toluene, chlorobenzene, and hexane.

A ninth aspect of the present disclosure, either alone or in combination with any other aspect, concerns the method of the sixth or eighth aspect, wherein the organic solvent further comprises oleic acid (OA).

A tenth aspect of the present disclosure, either alone or in combination with any other aspect, concerns the method of the sixth, eighth, or ninth aspect, wherein the organic solvent further comprises oleyamine (OAm).

An eleventh aspect of the present disclosure, either alone or in combination with any other aspect, concerns the method of any of the sixth to tenth aspects, wherein the method further comprises ultrasonication.

A twelfth aspect of the present disclosure, either alone or in combination with any other aspect, concerns the method of the eleventh aspect, wherein ultrasonication is provided to a water bath in which there is a container with the organic solvent.

A thirteenth aspect of the present disclosure, either alone or in combination with any other aspect, concerns the method of the eleventh or twelfth aspect, wherein ultrasonication is provided for a period of from about 30 minutes to about 400 minutes.

A fourteenth aspect of the present disclosure, either alone or in combination with any other aspect, concerns the method of the eleventh or twelfth aspect, wherein ultrasonication is provided at a frequency of from about 20 kiloHertz to about 10 megaHertz.

A fifteenth aspect of the present disclosure, either alone or in combination with any other aspect, concerns the method of the first or second aspect, wherein the volume of water further comprises a metal halide to dope the cesium-lead halide nanocrystal.

A sixteenth aspect of the present disclosure, either alone or in combination with any other aspect, concerns the method of the fifteenth aspect, wherein the metal halide is selected from the group consisting of aluminum bromide, aluminum chloride, and aluminum iodide.

A seventeenth aspect of the present disclosure, either alone or in combination with any other aspect, concerns the method of the first aspect, wherein the cesium halide is at least partially substituted with methylammonium or formamidinium.

An eighteenth aspect of the present disclosure, either alone or in combination with any other aspect, concerns a method of preparing a cesium-lead-halide powder or precipitate, comprising adding a cesium halide and a lead halide to a volume of water.

A nineteenth aspect of the present disclosure, either alone or in combination with any other aspect, concerns the method of the eighteenth aspect, wherein the cesium halide is selected from cesium bromide, cesium iodide, and cesium chloride.

A twentieth aspect of the present disclosure, either alone or in combination with any other aspect, concerns the method of the nineteenth aspect, further comprising applying heat to the volume of water at a temperature of from about 40 to 90° C. for a period of time of from about 30 minutes to about 400 minutes.

A twenty-first aspect of the present disclosure, either alone or in combination with any other aspect, concerns the method of the nineteenth aspect, wherein the volume of water further comprises a metal halide to dope the cesium-lead halide nanocrystal.

A twenty-second aspect of the present disclosure, either alone or in combination with any other aspect, concerns the method of the nineteenth aspect, wherein the cesium halide is substituted with methylammonium or formamidinium.

A twenty-third aspect of the present disclosure, either alone or in combination with any other aspect, concerns a cesium or cesium-substituted lead halide powder or lead halide nanocrystal prepared by any one of the first through twenty-second aspects.

The foregoing description of several aspects has been presented for purposes of illustration. It is not intended to be exhaustive or to limit the application to the precise forms disclosed, and obviously many modifications and variations are possible in light of the above teaching. It is understood that the disclosure may be practiced in ways other than as specifically set forth herein without departing from the scope of the disclosure. Any patents or publications mentioned in this specification are incorporated herein by reference to the same extent as if each individual publication is specifically and individually indicated to be incorporated by reference.

1. A method for preparing a cesium-lead-halide nanocrystal, comprising adding a cesium halide and a lead halide to a volume of water.

2. The method of claim 1, wherein the cesium halide is selected from the group consisting of cesium bromide, cesium iodide, and cesium chloride.

3. The method of claim 1, wherein the cesium halide and lead halide have the same molarity in the volume of water.

4. The method of claim 1, further comprising obtaining a precipitate from the volume of water and drying the precipitate.

5. The method of claim 4, further comprising applying heat to the precipitate at a temperature of from about 40 to 90° C. for a period of time of from about 30 minutes to about 400 minutes.

6. The method of claim 4, further comprising placing the precipitate in an organic solvent.

7. The method of claim 6, wherein the precipitate is provided at from about 0.02 mg to 1 mg per 3 to 15 mL of organic solvent.

8. The method of claim 6, wherein the organic solvent is selected from toluene, chlorobenzene, and hexane.

9. The method of claim 6, wherein the organic solvent further comprises oleic acid (OA).

10. The method of claim 6, wherein the organic solvent further comprises oleyamine (OAm).

11. The method of claim 6, wherein the method further comprises ultrasonication.

12. The method of claim 11, wherein ultrasonication is provided to a water bath containing the organic solvent.

13. The method of claim 11, wherein ultrasonication is provided for a period of from about 30 minutes to about 400 minutes.

14. The method of claim 11, wherein ultrasonication is provided at a frequency of from about 20 kiloHertz to about 10 megaHertz.

15. The method of claim 1, wherein the volume of water further comprises a metal halide to dope the cesium-lead halide nanocrystal.

16. The method of claim 15, wherein the metal halide is selected from the group consisting of aluminum bromide, aluminum chloride, and aluminum iodide.

17. The method of claim 1, wherein the cesium halide is at least partially substituted with methylammonium or formamidinium.

18. A method of preparing a cesium-lead-halide powder, comprising adding a cesium halide and a lead halide to a volume of water.

19. The method of claim 18, wherein the cesium halide is selected from cesium bromide, cesium iodide, and cesium chloride.

20. The method of claim 19, further comprising applying heat to the volume of water at a temperature of from about 40 to 90° C. for a period of time of from about 30 minutes to about 400 minutes.

21. The method of claim 19, wherein the volume of water further comprises a metal halide to dope the cesium-lead halide nanocrystal.

22. The method of claim 19, wherein the cesium halide is substituted with methylammonium or formamidinium.

23. (canceled)
